(19) United States
(12) Patent Application Publication
(10) Pub. No.: US 2011/0210343 A1
(43) Pub. Date: Sep. 1, 2011

(54) SEMICONDUCTOR WAFER

(75) Inventors: Fu-Bang CHEN, Hsinchu (TW); Kuo-Lung Fang, Hsinchu (TW); Kun-Fu Huang, Hsinchu (TW); Te-Chung Wang, Hsinchu (TW)

(73) Assignee: Lextar Electronics Corporation, Hsinchu (TW)

(21) Appl. No.: 12/859,825

(22) Filed: Aug. 20, 2010

(30) Foreign Application Priority Data
Mar. 1, 2010 (TW) 099105863

(51) Int. Cl. H01L 33/00; H01L 23/00

(52) U.S. Cl. 257/79; 257/620; 257/E23.002; 257/E33.055

(57) ABSTRACT

A semiconductor wafer includes a substrate, a first separating structure and a semiconductor stacked layer structure. The substrate has a first surface. The first separating structure is formed on the first surface to divide the first surface into a plurality of independent regions. The minimum area of each of the regions is more than or equal to one square inch. The semiconductor stacked layer structure is disposed on the first surface and the first separating structure. The semiconductor wafer can prevent bowing of the semiconductor wafer during an epitaxial growth process so as to enhance quality of the semiconductor wafer.

### CROSS-REFERENCE TO RELATED APPLICATION

This application claims the priority benefit of Taiwan application serial no. 099105863, filed on Mar. 1, 2010. The entirety of the above-mentioned patent application is incorporated herein by reference and made a part of this specification.

### BACKGROUND

1. Technical Field

The present invention relates to a semiconductor wafer, and more particularly relates to a semiconductor wafer with a relatively large size.

2. Description of the Related Art

Recently, various electronic components are manufactured from semiconductor wafers, such as a light-emitting diode.

The light-emitting diode has advantages of small size, long lifetime, low driving voltage, low power consumption, rapid response and good oscillation-proof, and has been widely used in electronic products, such as cars, computers, communication products or other consumer electronic products.

The semiconductor wafer of the light-emitting diode includes a substrate and a stacked structure formed on the substrate by epitaxy. The substrate can be sapphire. The stacked structure can be a III-V compound semiconductor layer, such as gallium nitride series.

However, the semiconductor wafer should be induced to bow, and quality of the semiconductor wafer is degraded in a process of manufacturing the above-mentioned light-emitting diode, because of different thermal expansion coefficient and lattice constant between the substrate and the stacked structure, and an accumulated stress in the stacked structure during the epitaxial growth process. Consequently, wavelengths of light emitted by the light-emitting diodes on the same semiconductor wafer should be non-uniformity.

Furthermore, if the diameter of the semiconductor wafer increases from two inch to three, four or more inch, the epitaxial stacked structure would be bowed more seriously.

What is needed, therefore, is a new semiconductor wafer and a new light-emitting diode that can overcome the above-mentioned shortcomings.

### BRIEF SUMMARY

The present invention relates to a semiconductor wafer, which can prevent bowing of the semiconductor wafer during an epitaxial growth process so as to enhance quality of the semiconductor wafer.

The present invention provides a semiconductor wafer, which includes a substrate, a first separating structure and a semiconductor stacked layer structure. The substrate has a first surface. The first separating structure is formed on the first surface to divide the first surface into a plurality of independent regions. The minimum area of each of the regions is more than or equal to one square inch. The semiconductor stacked layer structure is disposed on the first surface and the first separating structure.

The present invention provides a semiconductor wafer, which includes a substrate, a first separating structure and a semiconductor stacked layer structure. The substrate has a first surface. The first separating structure is formed on the first surface. Each first separating structure has two ends that are separated with each other. At least one of the two ends does not extend to an edge of the first surface. The semiconductor stacked layer structure is disposed on the first surface and the first separating structure.

The present invention provides a light-emitting diode, which includes a substrate, a first separating structure and a semiconductor stacked layer structure. The substrate has a first surface. The first separating structure is formed on the first surface to divide the first surface into a plurality of independent regions. The minimum area of each of the regions is more than or equal to one square inch. The semiconductor stacked layer structure is disposed on the first surface and the first separating structure.

The present invention provides a light-emitting diode, which includes a substrate, a first separating structure and a semiconductor stacked layer structure. The substrate has a first surface. The first separating structure is formed on the first surface. Each first separating structure has two ends that are separated with each other. At least one of the two ends does not extend to an edge of the first surface. The semiconductor stacked layer structure is disposed on the first surface and the first separating structure.

The present invention provides a semiconductor wafer, which includes a substrate, a first separating structure and a semiconductor stacked layer structure. The substrate has a first surface and a second surface. The first separating structure is formed on the first surface to divide the first surface into a plurality of independent regions. The minimum area of each of the regions is more than or equal to one square inch. The semiconductor stacked layer structure is disposed on the second surface.

The present invention provides a semiconductor wafer, which includes a substrate, a first separating structure and a semiconductor stacked layer structure. The substrate has a first surface and a second surface. The first separating structure is formed on the first surface. Each first separating structure has two ends that are separated with each other. At least one of the two ends does not extend to an edge of the first surface. The semiconductor stacked layer structure is disposed on the second surface.

The semiconductor wafer of the present invention includes the separating structure, so a stress that is accumulated in the semiconductor stacked layer structure during an epitaxial growth process can be released. Consequently, bowing of the semiconductor wafer can be reduced, and thus, quality of the semiconductor wafer can be enhanced.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic, top plan view of a semiconductor wafer according to a first embodiment of the present invention.

FIG. 2 is a side cross-sectional view of the semiconductor wafer of FIG. 1, taken along line II-II′ thereof.

FIG. 3 is a curvature graph of the semiconductor wafers in epitaxial growth processes.

FIGS. 4A-4E are schematic views of distribution types of separating structures of the semiconductor wafer.

FIG. 5 is a side cross-sectional view of a semiconductor wafer according to a second embodiment of the present invention.

FIG. 6 is a schematic, top plan view of a semiconductor wafer according to a third embodiment of the present invention.

FIG. 7 is a side cross-sectional view of the semiconductor wafer of FIG. 6, taken along line XII-XII′ thereof.

FIGS. 8A-8E are schematic views of distribution types of separating structures of the semiconductor wafer.

FIG. 9 is a schematic, top plan view of a semiconductor wafer according to a fourth embodiment of the present invention.

FIG. 10 is a schematic, top plan view of a semiconductor wafer according to a fifth embodiment of the present invention.

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

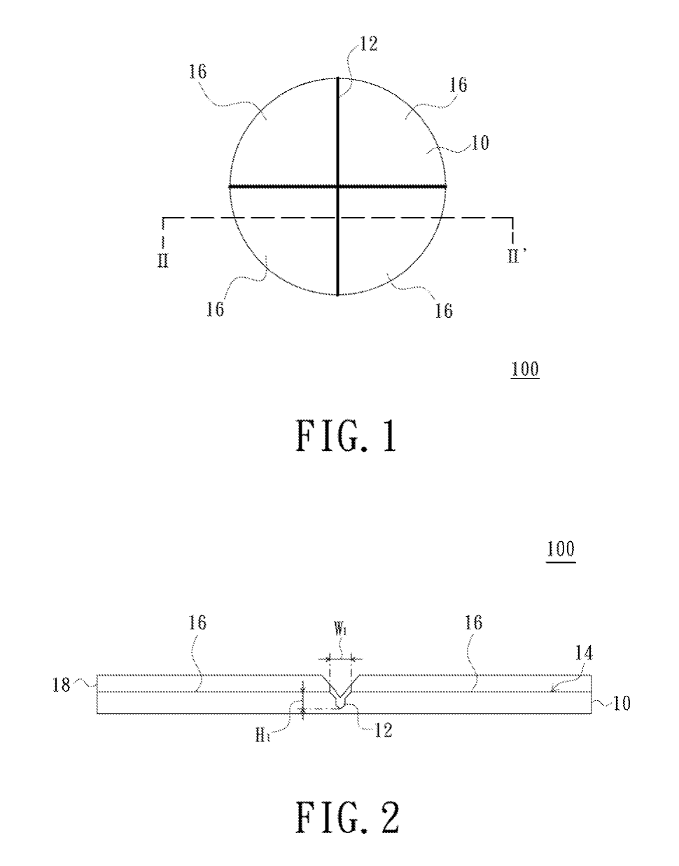

FIG. 1 is a schematic, top plan view of a semiconductor wafer according to a first embodiment of the present invention. FIG. 2 is a side cross-sectional view of the semiconductor wafer of FIG. 1, taken along line II-II′ thereof. Referring to FIGS. 1 and 2, the semiconductor wafer 100 of the first embodiment includes a substrate 10, at least one separating structure 12 and a semiconductor stacked layer structure 18. The substrate 10 has a surface 14. The separating structures 12 are formed on the surface 14, so as to divide the surface 14 into a plurality of independent regions 16. The minimum area of each of the regions 16 is more than or equal to one square inch. The semiconductor stacked layer structure 18 is disposed on the surface 14 and the separating structures 12. The semiconductor wafer 100 can be used in a light-emitting diode, such as, a laser emitting diode. The semiconductor wafer 100 can have a large size. For example, the diameter of the semiconductor wafer 100 is more than 3 inch.

Material of the substrate 10 can be sapphire, silicon, silicon carbide or metal. Material of the semiconductor stacked layer structure 18 can be selected from compound semiconductor including aluminum (Al), gallium (Ga), indium (In), nitrogen (N), phosphorus (P) or arsenic (As), such as gallium nitride series compound semiconductor or aluminum gallium indium phosphide series compound semiconductor. The semiconductor stacked layer structure 18 can include a first conductive semiconductor layer (not shown), a light-emitting layer (not shown) and a second conductive semiconductor layer (not shown). The first conductive semiconductor layer is adjacent to the surface 14. The light-emitting layer is located between the first conductive semiconductor layer and the second conductive semiconductor layer. The light-emitting layer can be a multiple quantum well (MQW) structure.

The separating structures 12 are used to divide the surface 14 into the independent regions 16. As such, a stress that is accumulated in the semiconductor stacked layer structure 18 during an epitaxial growth process can be released. Consequently, bowing of the semiconductor wafer 100 can be reduced, and thus, quality of the semiconductor wafer 100 can be enhanced.

In details, in the embodiment, the separating structures 12 are trenches formed on the surface 14, as shown in FIG. 2. A depth H₁ of each of the separating structures 12 can be in the range from 4 microns to 50 microns, and a width W₁ of each of the separating structures 12 can be in the range from 8 microns to 250 microns. In addition, a cross-section of each trench can be U-shaped, V-shaped, rectangular or polygonal. The separating structures 12 can be formed by etching, laser cutting, diamond knife cutting or imprinting.

Because the semiconductor wafer 100 includes the separating structures 12, the semiconductor stacked layer structure 18 right over the separating structures 12 may be relatively thin or ruptured during the epitaxial growth process. As such, the stress accumulated in the semiconductor stacked layer structure 18 can be released. Consequently, bowing of the semiconductor wafer 100 can be reduced, and thus, quality of the semiconductor wafer 100 can be enhanced. When the semiconductor wafer 100 is used in the light-emitting diode, uniformity of wavelengths of light emitted by the light-emitting diodes can be improved due to the stress being released and the improved quality of the semiconductor wafer 100.

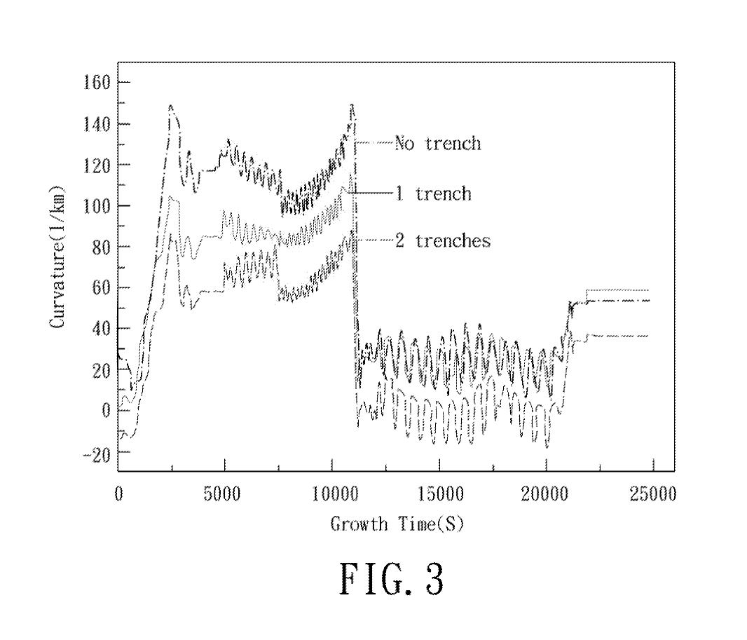

To further verify that the separating structures 12 may reduce or prevent bowing of the semiconductor wafer 100, the relationship between the number of separating structures 12 and the bowing of the semiconductor wafers 100 is tested, and the results are shown in FIG. 3. Referring to FIG. 3, when the semiconductor stacked layer structures are epitaxially grown for about 11000 seconds (that is the height of the semiconductor stacked layer structures grows to about 4 microns), the semiconductor stacked layer structures have maximum curvature. Furthermore, the curvature of the semiconductor wafer with two separating structures is the minimum, the curvature of the semiconductor wafer with one separating structure is the second, and the curvature of the semiconductor wafer without separating structures is the maximum.

Table 1 shows the tested curvature values, when the semiconductor stacked layer structures are epitaxially grown for about 11000 seconds. Referring to table 1 and FIG. 3, when the semiconductor stacked layer structures are epitaxially grown for about 11000 seconds, the curvature of the semiconductor wafer with two separating structures is 80 (l/km), the curvature of the semiconductor wafer with one separating structure is 110 (l/km), and the curvature of the semiconductor wafer without separating structures is 145 (l/km). Thus it can be seen that the separating structure 12 may reduce or prevent bowing of the semiconductor wafer 100 definitely.

TABLE 1

| Semiconductor Wafer | Curvature |
|---|---|
| n-GaN 4 um, without separating structures | 145 |
| n-GaN 4 um, with one separating structure | 110 |
| n-GaN 4 um, with two separating structures | 80 |
| Reference | 5 |

In addition, because the semiconductor wafer 100 has the relatively large size, and the minimum area of each of the regions 16 is more than or equal to one square inch, the semiconductor wafer 100 may facilitate the preparation of the large size light-emitting diode that has good quality. Therefore, application of the light-emitting diode can be expanded.

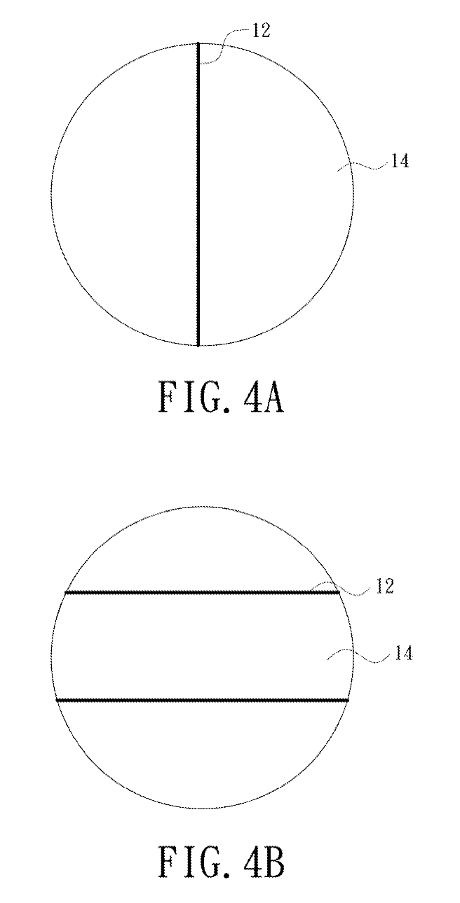

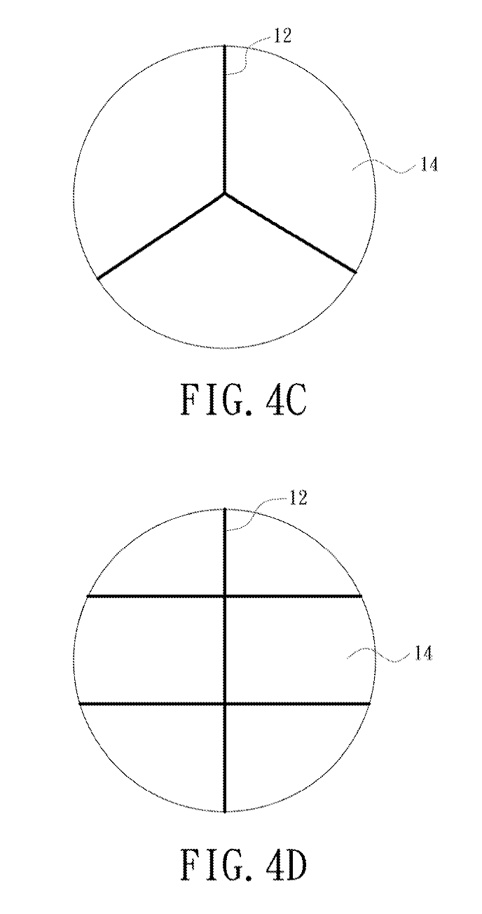

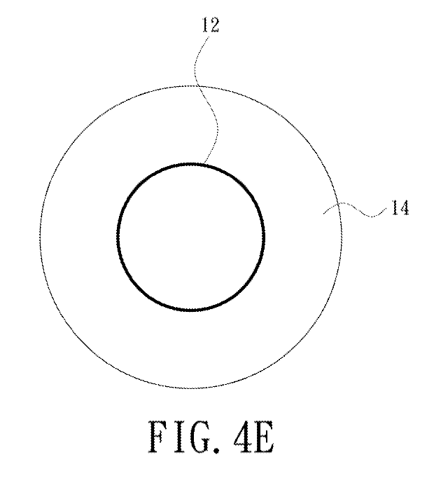

It should be noted that, the distribution type of the separating structures 12 can be other types. For example, referring to FIGS. 4A-4E, other distribution types of the separating structures 12 on the surface 14 are shown.

Referring to FIG. 4A, one separating structure 12 is formed on the surface 14, and the separating structure 12 divides the surface 14 into two independent regions. Referring to FIG. 4B, a plurality of separating structures 12 are formed on the surface 14, the plurality of separating structures 12 are not intersected with each other, and two ends of each of the separating structures 12 extend to an edge of the surface 14, so that the separating structures 12 divide the surface 14 into a plurality of independent regions. Referring to FIG. 4C, a plurality of separating structures 12 are formed on the surface 14, one end of each of the separating structures 12 extends to an edge of the surface 14, and another ends of the separating structures 12 are intersected at a predetermined point, so that the separating structures 12 divide the surface 14 into a plurality of independent regions. In the embodiment, the predetermined point can be a midpoint of the surface 14, and the present invention is not limited herein. Referring to FIG. 4D, a plurality of separating structures 12 are formed on the surface 14, two ends of each of the separating structures 12 extend to an edge of the surface 14, one of the separating structures 12 is intersected with the other separating structures 12 that are parallel with each other, so that the separating structures 12 divide the surface 14 into a plurality of independent regions. Referring to FIG. 4E, one separating structure 12 is formed on the surface 14, and the separating structure 12 is circular, so that the separating structure 12 divides the surface 14 into two independent regions. In the embodiment, the separating structure 12 and an edge of the surface 14 are concentric circles, and the present invention is not limited herein.

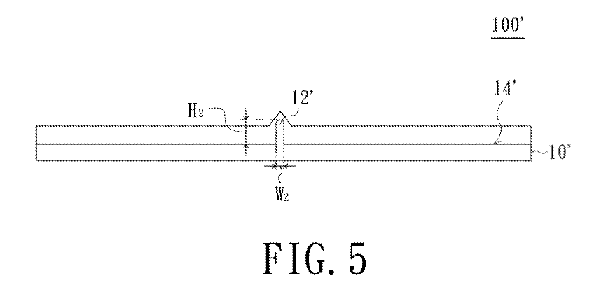

The separating structures that are described in the above embodiments are the grooves. In other embodiments, the separating structure can be a protrusion. FIG. 5 is a side cross-sectional view of a semiconductor wafer according to a second embodiment of the present invention. Referring to FIG. 5, the semiconductor wafer 100′ is similar in principle to the semiconductor wafer 100 of the first embodiment. However, in the semiconductor wafer 100′, a separating structure 12′ formed on a surface 14′ of the substrate 10′ is a protrusion. In addition, a cross-section of the protrusion can be triangular, rectangular, polygonal or arc-shaped.

A height H₂ of the separating structure 12′ can be more than or equal to 4 microns, and a width W₂ of the separating structure 12′ can be in the range from 8 microns to 250 microns. The separating structure 12′ can be formed by etching, sputtering, physical vapor deposition or printing. Particularly, if the separating structure 12′ is formed by sputtering, physical vapor deposition or printing, material of the separating structure 12′ should be heat-stable material, such as silicon dioxide, silicon nitride or metal.

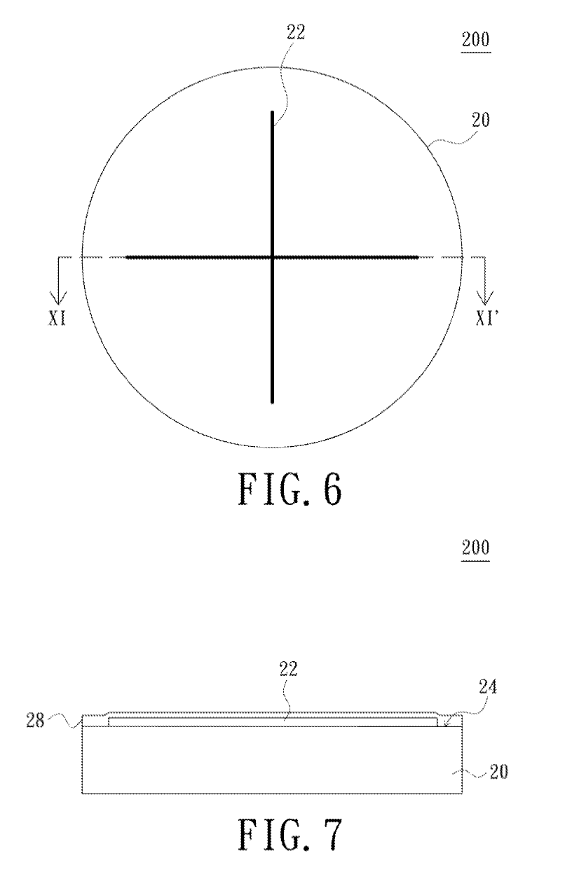

FIG. 6 is a schematic, top plan view of a semiconductor wafer according to a third embodiment of the present invention. FIG. 7 is a side cross-sectional view of the semiconductor wafer of FIG. 6, taken along line XII-XII′ thereof. Referring to FIGS. 6 and 7, the semiconductor wafer 200 is similar in principle to the semiconductor wafer 100 of the first embodiment.

However, in the semiconductor wafer 200, at lease one separating structure 22 is formed on a first surface 24 of a substrate 20, each separating structure 22 has two ends that are separated with each other, and at least one of the two ends does not extend to an edge of the surface 24.

In details, there are two separating structures 22. Each of the two separating structures 22 is elongate. The two ends of each of the two separating structures 22 do not extend to the edge of the surface 24, and the two separating structures 22 are intersected with each other at midpoints thereof.

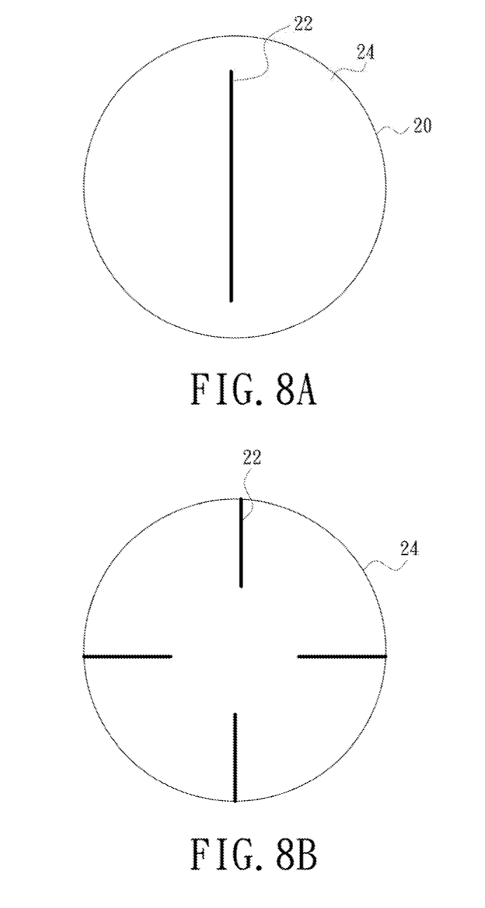

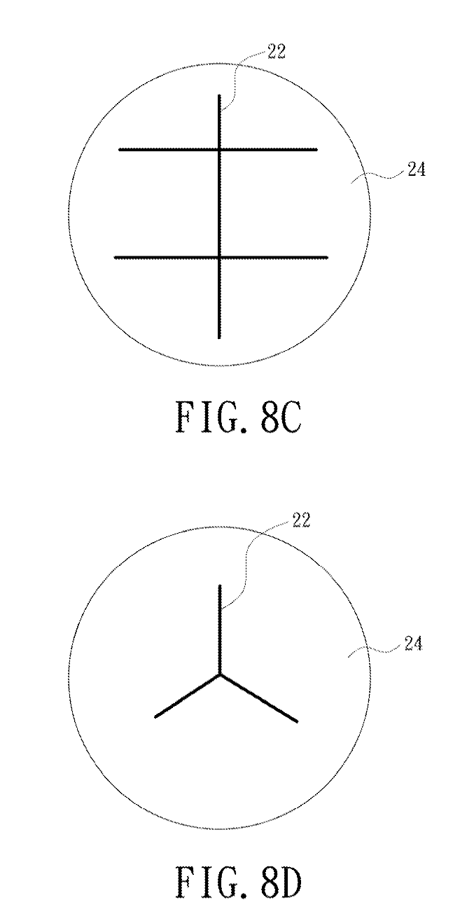

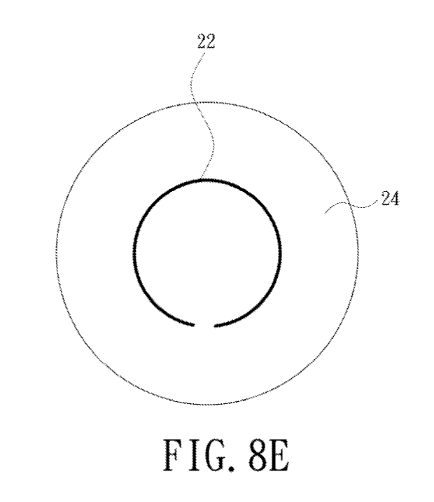

It should be noted that, the distribution type of the separating structures 22 can be other types. For example, referring to FIGS. 8A-8E, other distribution types of the separating structures 22 on the surface 24 are shown.

Referring to FIG. 8A, one separating structure 22 is formed on the surface 24 of the substrate 20, and two ends of the separating structure 22 do not extend to an edge of the surface 24. Referring to FIG. 8B, a plurality of separating structures 22 are formed on the surface 24, one end of each of the separating structures 22 extends to an edge of the surface 24, and the separating structures 22 are not intersected with each other. Referring to FIG. 8C, a plurality of separating structures 22 are formed on the surface 24, two ends of each of the separating structures 22 do not extend to an edge of the surface 24, and only one of the separating structures 22 pass through a midpoint of the surface 24. Referring to FIG. 8D, a plurality of separating structures 22 are formed on the surface 24, two ends of each of the separating structures 22 do not extend to an edge of the surface 24, and one of the two ends of the separating structures 22 passes through a predetermined point. In the embodiment, the predetermined point can be a midpoint of the surface 24, and the present invention is not limited herein. Referring to FIG. 8E, one separating structure 22 is formed on the surface 24, and the separating structure 22 is arc-shaped.

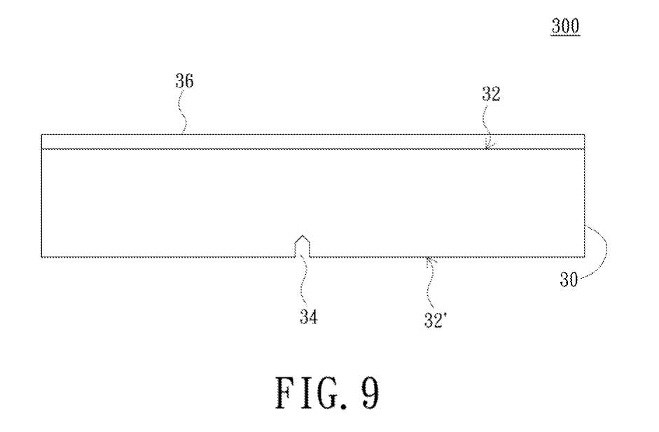

It should be understood that, the separating structure can also be formed on a surface of the substrate that is away from the semiconductor stacked layer structure. FIG. 9 is a side cross-sectional view of a semiconductor wafer according to a fourth embodiment of the present invention. Referring to FIG. 9, a semiconductor wafer 300 includes a substrate 30, at least one separating structure 34 and a semiconductor stacked layer structure 36. The substrate 30 has a first surface 32 and a second surface 32′. The separating structure 34 is formed on the second surface 32′. The semiconductor stacked layer structure 36 is disposed on the first surface 32. The separating structure 34 can be a trench or a protrusion. In the embodiment, the separating structure 34 is the trench. A structure and a manufacturing method of the separating structure 34 can be the same or similar to that of the separating structure of the above embodiments, and material of the semiconductor stacked layer structure 36 can be the same or similar to that of the semiconductor stacked layer structure of the above embodiments.

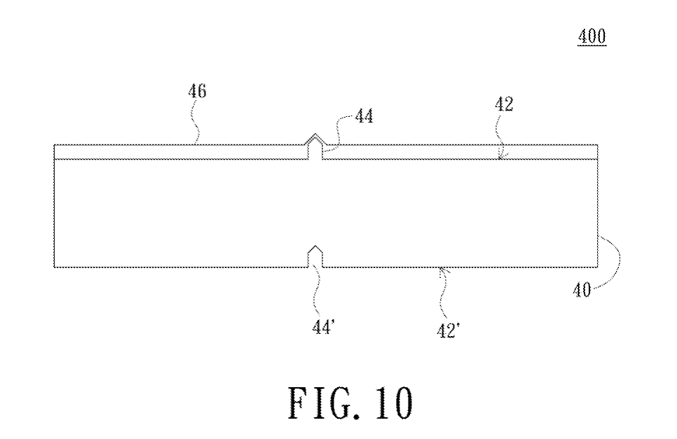

In addition, the separating structures can also be formed on the two surface of the substrate. FIG. 10 is a side cross-sectional view of a semiconductor wafer according to a fifth embodiment of the present invention. Referring to FIG. 10, a semiconductor wafer 400 includes a substrate 40, at least one first separating structure 44, at least one second separating structure 44′ and a semiconductor stacked layer structure 46. The substrate 40 has a first surface 42 and a second surface 42′. The first separating structure 44 is formed on the first surface 42. The second separating structure 44′ is formed on the second surface 42′. The semiconductor stacked layer structure 46 is disposed on the first surface 42 and the first separating structure 44. The first separating structure 44 or the second separating structure 44′ can be a trench or a protrusion. In the embodiment, the first separating structure 44 is the protrusion, and the second separating structure 44′ is the trench. A structure and a manufacturing method of the first separating structure 44 or the second separating structure 44′ can be the same or similar to that of the separating structure of the above embodiments, and material of the semiconductor stacked layer structure 46 can be the same or similar to that of the semiconductor stacked layer structure of the above embodiments.

In summary, because the semiconductor wafer of the present invention includes the separating structure, a stress that is accumulated in the semiconductor stacked layer structure during an epitaxial growth process can be released. Consequently, bowing of the semiconductor wafer can be reduced, and thus, quality of the semiconductor wafer can be enhanced.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A semiconductor wafer, comprising:
a substrate having a first surface;
at least one first separating structure formed on the first surface to divide the first surface into a plurality of independent regions, the minimum area of each of the regions being more than or equal to one square inch; and
a semiconductor stacked layer structure disposed on the first surface and the at least one first separating structure.

2. The semiconductor wafer as claimed in claim 1, wherein material of the substrate is sapphire, silicon, silicon carbide or metal.

3. The semiconductor wafer as claimed in claim 1, wherein each first separating structure is a trench or a protrusion.

4. The semiconductor wafer as claimed in claim 3, wherein a depth of the trench is in the range from 4 microns to 50 microns.

5. The semiconductor wafer as claimed in claim 3, wherein a height of the protrusion is more than or equal to 4 microns.

6. The semiconductor wafer as claimed in claim 1, wherein the substrate further has a second surface, and at least one second separating structure is formed on the second surface.

7. The semiconductor wafer as claimed in claim 6, wherein each second separating structure is a trench or a protrusion.

8. A semiconductor wafer, comprising:
a substrate having a first surface;
at least one first separating structure formed on the first surface, each first separating structure having two ends which are separated with each other, at least one of the two ends not extending to an edge of the first surface; and
a semiconductor stacked layer structure disposed on the first surface and the at least one first separating structure.

9. The semiconductor wafer as claimed in claim 8, wherein material of the substrate is sapphire, silicon, silicon carbide or metal.

10. The semiconductor wafer as claimed in claim 8, wherein each first separating structure is a trench or a protrusion.

11. The semiconductor wafer as claimed in claim 10, wherein a depth of the trench is in the range from 4 microns to 50 microns.

12. The semiconductor wafer as claimed in claim 10, wherein a height of the protrusion is more than or equal to 4 microns.

13. The semiconductor wafer as claimed in claim 8, wherein the substrate further has a second surface, and at least one second separating structure is formed on the second surface.

14. The semiconductor wafer as claimed in claim 13, wherein each second separating structure is a trench or a protrusion.

15. A light-emitting diode, comprising:
a substrate having a first surface;
at least one first separating structure formed on the first surface to divide the first surface into a plurality of independent regions, the minimum area of each of the regions being more than or equal to one square inch; and
a semiconductor stacked layer structure disposed on the first surface and the at least one first separating structure.

16. The light-emitting diode as claimed in claim 15, wherein material of the substrate is sapphire, silicon, silicon carbide or metal.

17. The light-emitting diode as claimed in claim 15, wherein each first separating structure is a trench or a protrusion.

18. The light-emitting diode as claimed in claim 15, wherein the semiconductor stacked layer structure comprises a first conductive semiconductor layer, a light-emitting layer and a second conductive semiconductor layer, the first conductive semiconductor layer is adjacent to the first surface, and the light-emitting layer is located between the first conductive semiconductor layer and the second conductive semiconductor layer.

19. The light-emitting diode as claimed in claim 15, wherein the substrate further has a second surface, and at least one second separating structure is formed on the second surface.

20. The light-emitting diode as claimed in claim 19, wherein each second separating structure is a trench or a protrusion.

21. A light emitted diode, comprising:
a substrate having a first surface;
at least one first separating structure formed on the first surface, each first separating structure having two ends that are separated with each other, at least one of the two ends not extending to an edge of the first surface; and
a semiconductor stacked layer structure disposed on the first surface and the at least one first separating structure.

22. The light-emitting diode as claimed in claim 21, wherein material of the substrate is sapphire, silicon, silicon carbide or metal.

23. The light-emitting diode as claimed in claim 21, wherein each first separating structure is a trench or a protrusion.

24. The light-emitting diode as claimed in claim 21, wherein the semiconductor stacked layer structure comprises a first conductive semiconductor layer, a light-emitting layer and a second conductive semiconductor layer, the first conductive semiconductor layer is adjacent to the first surface, and the light-emitting layer is located between the first conductive semiconductor layer and the second conductive semiconductor layer.

25. The light-emitting diode as claimed in claim 21, wherein the substrate further has a second surface, and at least one second separating structure is formed on the second surface.

26. The light-emitting diode as claimed in claim 25, wherein each second separating structure is a trench or a protrusion.

27. A semiconductor wafer, comprising:
a substrate having a first surface and a second surface;
at least one first separating structure formed on the first surface to divide the first surface into a plurality of independent regions, the minimum area of each of the regions being more than or equal to one square inch; and
a semiconductor stacked layer structure disposed on the second surface.

28. The semiconductor wafer as claimed in claim 27, wherein material of the substrate is sapphire, silicon, silicon carbide or metal.

29. The semiconductor wafer as claimed in claim 27, wherein each first separating structure is a trench or a protrusion.

30. A semiconductor wafer, comprising:
a substrate having a first surface and a second surface;
at least one first separating structure formed on the first surface, each first separating structure having two ends that are separated with each other, at least one of the two ends not extending to an edge of the first surface; and
a semiconductor stacked layer structure disposed on the second surface.

31. The semiconductor wafer as claimed in claim 30, wherein material of the substrate is sapphire, silicon, silicon carbide or metal.

32. The semiconductor wafer as claimed in claim 30, wherein each first separating structure is a trench or a protrusion.
